(19) United States
(12) Patent Application Publication
(10) Pub. No.: US 2009/0135935 A1
(43) Pub. Date: May 28, 2009

(54) DIGITAL TV RECEIVER HAVING BUILT-IN DIVERSITY STRUCTURE

(75) Inventors: LIN YANG, FREMONT, CA (US); SYANG-MYAU HWANG, CUPERTINO, CA (US)

Correspondence Address: FRANK F. TIAN, 331-4A THIRD AVENUE, LONG BEACH, NJ, 07740, US

(73) Assignee: LEGEND SILICON CORP, FREMONT, CA (US)

(21) Appl. No.: 11/946,800

(22) Filed: Nov. 28, 2007

(51) Int. Cl. H04L 23/02; H03D 1/00; H04L 27/06

(52) U.S. Cl. 375/265; 375/340

(57) ABSTRACT

A receiver is provided that comprises: a channel estimator; a first path for feeding the estimated information into a frequency domain equalizer; a second path for feeding the estimated information into a time domain equalizer; and a combiner or selector to combine or select equalized information from the frequency domain equalizer and the time domain equalizer.

### FIELD OF THE INVENTION

The present invention relates generally to communication devices or receivers. More specifically, the present invention relates to a digital television receiver having built-in diversity structure.

### BACKGROUND

Digital television receivers are known to use frequency equalizer for equalization in the frequency domain. See FIG. 1. In U.S. Pat. No. 6,912,258, a frequency-domain equalizer for terrestrial digital TV reception is shown, wherein a single integrated circuit multi-standard demodulator is disclosed that includes an adaptive inverse channel estimator for frequency domain equalization which employs a recursive least square cost function in estimating the inverse channel from the received signal and an error estimate. Utilizing a diagonal correlation matrix, a solution thereto may be determined utilizing fewer computational resources than required by conventional frequency domain equalizers, shifting from a computational intensive to memory intensive implementation. The memory requirement is fully satisfied by memory available within conventional OFDM decoders, and the necessary computational resources may be readily mapped to the resources available within such decoders, improving integrated circuit cost-effectiveness of the multi-standard demodulator.

Further, receivers are known to use time equalizer for equalization in the time domain. See FIG. 2. In U.S. Pat. No. 7,248,648 to Erving, et al. discloses an Efficient reduced complexity windowed optimal time domain equalizer for discrete multitone-based DSL modems

Embedding the FEQ in-side of the TEQ is known. In U.S. Pat. No. 7,042,937 discloses Hybrid frequency-time domain equalizer having a channel decoder that employs a hybrid frequency-time domain equalizer for effectively combining a frequency domain equalizer with a time domain equalizer to achieve superior static and dynamic multi-path performance compared to conventional decision feedback equalizers. A frequency domain equalizer structure is included within the forward path of a time domain, decision feedback equalizer, with both the frequency domain and time domain portions employing a common error vector. Updates to the taps (frequency bins) may be adapted individually, or fully within the frequency domain without altering the feedback filter. Improved performance, including performance for noisy channels with deep notches, is achieved, and the frequency domain equalizer portion is relieved from equalizing minimum phase zeros of the channel. In other words, the frequency domain equalizer structure is included within the forward path of a time domain, decision feedback equalizer.

In practical application, especially in mobile applications where channel conditions change, there is a need for improved equalization by suitably introducing diversity or redundancy into a DTV receiver.

### SUMMERY OF THE INVENTION

A digital television receiver having built-in diversity structure is provided.

A method to introduce diversity into a digital television receiver is provided.

A digital television receiver is provided that comprises: a channel estimator; a first path for feeding the estimated information into a frequency domain equalizer; a second path for feeding the estimated information into a time domain equalizer; and a combiner or selector to combine or select equalized information from the frequency domain equalizer and the time domain equalizer.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of a first prior art receiver.

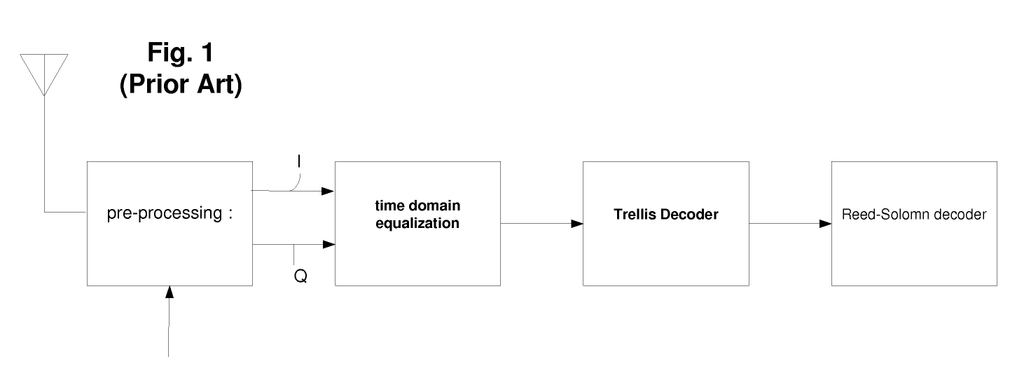

FIG. 2 is an example of a second prior art receiver.

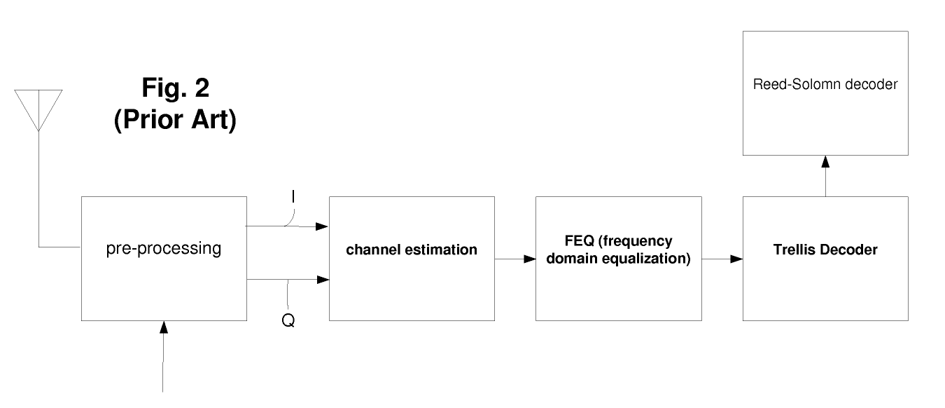

FIG. 3 is an example of a DTV receiver structure in accordance with some embodiments of the invention.

FIG. 4 is an example of a flowchart in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to combining equalized information from a first path and a second path. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of relating to a method for combining equalized information from a first path and a second path. In the exemplified embodiments, it is noted that the processors include Finite State Machines, which are used in the preferred embodiment. The non-processor circuits may include, but are not limited to, a radio receiver, a radio transmitter, signal drivers, clock circuits, power source circuits, and user input devices. As such, these functions may be interpreted as steps of a method for combining equalized information from a first path and a second path. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

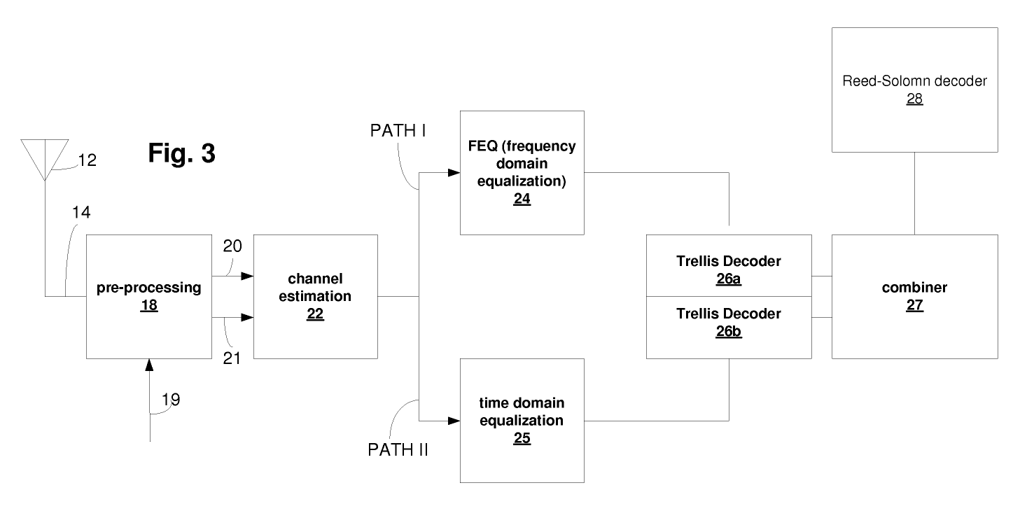

Referring to FIG. 3, a preferred embodiment of the present invention is shown. An antenna 12 receives a DTV signal 14 (both audio and video signals) that are down converted into an intermediate frequency (IF) DTV signal 14. DTV signal 14 is subjected to a set of preprocessing actions 18 including down-conversion, timing recovery, and carrier recovery using a reference 19 resulting in the preprocessed DTV signal 14 being converted into their respective 120 and Q 21 digital components, which forms the input to channel estimation block 22 or channel estimator. The estimated information of block 22 is used in two separated equalization paths. A first path is subjected to frequency domain equalization (FEQ) 24. A second path is subjected to time domain equalization (TEQ) 25. FEQ 24 and TEQ 25, i.e. path I and path II, each processes identical or substantially similar estimated information coming out of block 22. For FEQ 24, due to the inherent quality therein, is linear. Whereas, TEQ 25 due to the inherent quality therein is non-linear. The equalized frequency information and the equalized timing information are separately subjected to a Trellis decoder block 26a and 26b respectively.

As can be seen, some redundancy is established in this invention by at least selectively using either equalized frequency information, or equalized timing information. The decoded information of Trellis Decoder 26a and trellis decoder 26b are combined or selected by a combiner 27. For example, if path I possesses a better signal quality according to a predetermined value in relation to path II, path I is selected. On the hand, if path II possesses a better signal quality according to a predetermined value in relation to path I, path II is selected. A third choice is to combine part of path I and path II. For example, a linear combination of both paths is contemplated if path I and path II quality are compatible. The combined/selected Trellis decoded information is further subjected to Reed-Solomon decoder 28, and possible further processing (not shown). It is noted that in block 26, the Trellis decoder therein may be a part of a specific standard such as the DTV standard of ATSC. Further, the Trellis decoder and a form of error correction are combined therein.

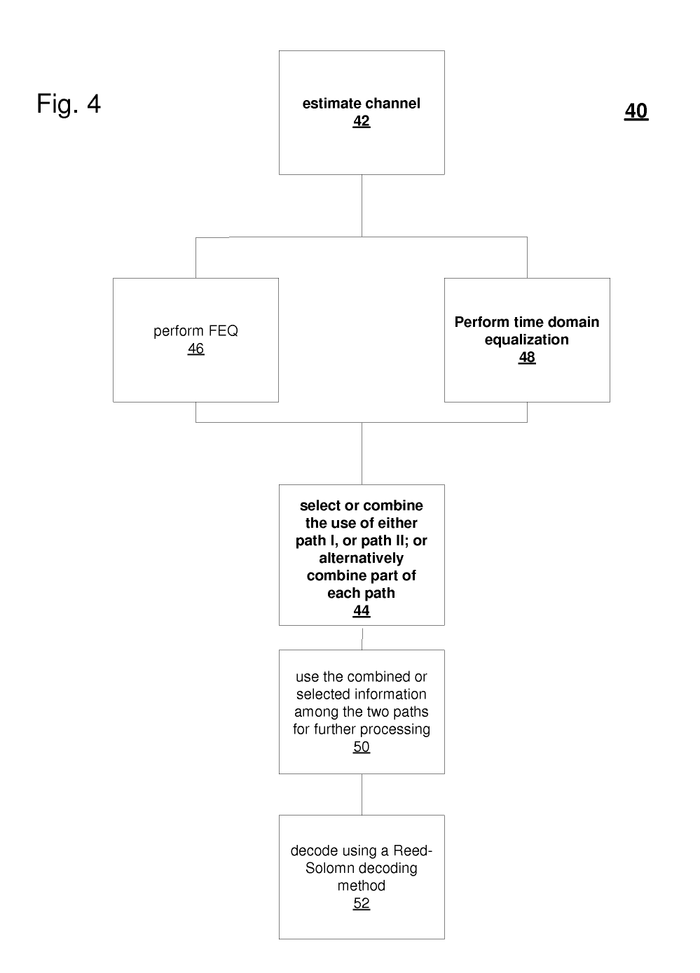

FIG. 4 is a flowchart 40 depicting combiner process for the present invention. Channel estimation is performed on a pair of digital signal streams both received and converted from an analog wireless signal (Step 42). A determination is made regarding whether to select or combine the use of either path I, or path II; or alternatively combine part of each path of FIG. 3 (Step 42). Separately, frequency domain equalization (FEQ) and time domain equalizations are performed (Steps 46 and 48). If a condition is met equalized frequency information and equalized timing information are used. In other words, select or combine the use of either path I, or path II; or alternatively combine part of each path is provided. In turn, the selected or combined information of either path I, or path II or a predetermined part thereof are used for processing (Step 50). As can be seen, the present invention provides a build-in diversity structure, which has the TEQ and FEQ working independently, thereby giving us the full requisite, diversity property. In other words, path I and path II are independent in that each path respectively performs TEQ and FEQ independent of the other path. Furthermore, neither path is embedded in the other path such as the FEQ in-side of the TEQ.

The combined or selected information among the two paths are used for further processing down stream of the receiver. Further decode using a Reed-Solomn decoding method is provided (Step 52). Furthermore, the receiver may be an ATSC receiver suitable for the terrestrial DTV system in such countries as the United States of America.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A receiver comprising:
a channel estimator;
a first path for feeding the estimated information into a frequency domain equalizer;
a second path for feeding the estimated information into a time domain equalizer; and
a combiner or selector to combine or select equalized information from the frequency domain equalizer and the time domain equalizer.

2. The receiver of claim 1, wherein the combiner uses a Trellis decoder to combine the two separately equalized data sequence.

3. The receiver of claim 1, wherein the first the first equalizing device comprises a time domain equalizer (TEQ).

4. The receiver of claim 1, wherein the second equalizing device comprises a frequency domain equalizer a frequency domain equalizer (FEQ).

5. The receiver of claim 1, wherein the first equalizing device and the second equalizing device perform actions independent of each other.

6. A method comprising the steps of:
providing a channel estimator;
providing a first path for feeding the estimated information into a first equalizing device;
a second path for feeding the estimated information into a second equalizing device; and
a combiner or selector to combine or select equalized information from the first equalizing device and the second equalizing device.

7. The method of claim 6, wherein the combiner uses a Trellis decoder to combine the two separately equalized data sequence.

8. The method of claim 6, wherein the first the first equalizing device comprises a time domain equalizer (TEQ).

9. The method of claim 6, wherein the second equalizing device comprises a frequency domain equalizer a frequency domain equalizer (FEQ).

10. The method of claim 6, wherein the first equalizing device and the second equalizing device perform actions independent of each other.
